(19) United States
(12) Patent Application Publication
(10) Pub. No.: US 2011/0240121 A1
(43) Pub. Date: Oct. 6, 2011

(54) Nanocrystalline Superlattice Solar Cell

(75) Inventor: Vikram L. Dalal, Ames, IA (US)

(73) Assignee: IOWA STATE UNIVERSITY RESEARCH FOUNDATION, INC., Ames, IA (US)

(21) Appl. No.: 12/753,405

(22) Filed: Apr. 2, 2010

(51) Int. Cl. H01L 31/0376; H01L 29/04

(52) U.S. Cl. 136/258; 257/28; 257/E31.048; 257/E29.003

(57) ABSTRACT

A nanocrystalline superlattice solar cell utilizing a superlattice constructed from alternating amorphous and nanocrystalline layers is provided. The amorphous layers of the superlattice include Germanium. In one embodiment the Germanium content is homogeneous across the amorphous layer. Alternatively, the Germanium content is graded across the amorphous layer from a lower content to a greater content as the amorphous layer is grown. The grading of Germanium content can vary from 0% or greater at a boundary with the preceding layer to 100% or less at a boundary with a subsequent layer. The grading may be continuous or may occur in discreet step increases in Germanium content.

### STATEMENT REGARDING FEDERALLY SPONSORED RESEARCH AND DEVELOPMENT

This invention was made in part with Government support under Grant Numbers ECCS0501251 and ECCS0824091 awarded by the National Science Foundation. The Government has certain rights in this invention.

### FIELD OF THE INVENTION

This invention generally relates to nanocrystalline Silicon solar cells, and more particularly to solar cells utilizing a superlattice of alternating amorphous and nanocrystalline Silicon layers.

### BACKGROUND OF THE INVENTION

Cost effective solar-electric energy conversion is a significant energy technology which is becoming increasingly important for the world. Direct solar-electric energy conversion using photovoltaic (solar cell) technology has grown exponentially over the last few years, as the costs have decreased from approximately $100/W in the late 1960's to the current level of approximately $3.50/W. This leads to electric energy generation costs of approximately 20-25 c/kWh. The current worldwide production of solar cells is approximately 3.4 GW/year. This is equivalent to the power produced by almost four nuclear power plants in a single year. To compare, not a single nuclear plant has been ordered in the United States in the last thirty years.

Solar cell panel production has been growing at an annual growth rate of approximately 40%/year over the last ten years, and the current worldwide revenue from photovoltaic (PV) systems is about $17.8 billion/year. The solar cell industry raised nearly $10 billion dollars worldwide in 2007 to build their plants, with almost $5.3 billion dollars coming as equity contribution. As these numbers demonstrate, the solar cell industry is a major growth industry worldwide.

Indeed, the demand for solar cells to produce electric power is being driven both by market pull because of government subsidies (as in Germany) and by its improving economic competitiveness with conventional power, particularly where sun shines brightly and power costs are high, e.g., California. In California, entire new housing developments have solar cells built-in on their roofs, with the cells providing excess power during daytime which is sold to the grid, and with the grid providing nighttime power to the homes. The daytime tariffs for electricity consumption in California are very high (approximately 15-20 c/kWh), because the peak power produced during daytime relies on very expensive natural gas, which is now costing upward of $10.00/MMBTU.

Unfortunately, the costs of solar cell panels, after continuously reducing for approximately 20 years, have increased in the last two years. This is likely because 88% of the world's production of solar cells relies on the use of crystalline or multi-crystalline Silicon wafers, which use very expensive feedstock of purified poly Silicon. Poly Silicon costs about $110-120/kg today. The Silicon wafers used in the solar cell panels are typically about 270-300 micrometers thick. These wafers are cut using multi-blade diamond saw from a Silicon boule. The combination of cutting loss and thickness means that approximately 600 micrometer thickness of Silicon is needed for making a crystalline Silicon solar cell.

The typical solar-to-electric conversion efficiency for crystalline Silicon solar cells currently in production is approximately 15%. This means that a panel which is one square meter in area produces about 150 W. Using the 600 micrometer thickness of Silicon translates into 10 kg of Silicon per kW of power produced, or at $120/kg, approximately $1,200/kW for Silicon alone. This is why the retail costs of the finished panel, which includes cells, encapsulation, front glass window, frame, etc., are now averaging about $4,800/kW. At these costs, electricity produced in sunny climates costs about 20-25 c/kWh, which is much too high to compete against power produced, e.g., from coal.

Recognizing that the current costs to produce electricity from such solar panels is not cost competitive, the U.S. Department of Energy has set a goal of 10 c/kWh for solar power. However, it is very unlikely that crystalline Silicon wafer technology will ever be able to achieve such costs, given the high cost of the Silicon wafers themselves. While the current shortage of Silicon throughout the world will be ameliorated to a certain extent by the multitude of poly Silicon feedstock plants that are currently being built in Norway, the U.S., and China, given that the industry is growing at approximately 40%/year, the new poly Silicon plants are not going to be able to meet the demand for quite some time.

Recognizing this limitation, thin film solar cell technology that uses only 2 micrometers of Silicon, not 600 micrometers, has been explored. Assuming that such thin film solar cell technology can achieve the same performance of approximately 15% conversion efficiency, and also that such cells could be manufactured using automated processing, it is possible to lower the costs of producing electricity to the 10 c/kWh goal set by the U.S. Department of Energy from the present 20-25 c/kWh.

Currently, three different types of thin film materials are being used to produce the thin film solar cells. These types include thin film Silicon and its alloys, Cadmium Telluride, and copper-indium-selenide. Unfortunately, these existing thin Silicon technologies are not very efficient, achieving only approximately 8% conversion efficiency in production panels. They also suffer from an approximate 10% performance degradation over time, which presents a major disadvantage of this technology, particularly compared with the 14-15% conversion efficiency achieved in production of crystalline Silicon based modules.

Another problem is that for efficient solar conversion using thin films, a multi-junction or tandem cell based on combining amorphous Silicon as a top cell with nanocrystalline (nano) thin film Silicon as the bottom cell is typically used. The idea in such a tandem cell is to split photons between two cells with different bandgaps, so as to minimize thermodynamic loss in each cell, and thereby achieve higher conversion efficiency. In principle, such cells can give solar conversion efficiencies of approximately 20%. Currently, however, the best conversion efficiencies in the lab are still only approximately 15%. Unfortunately, in such tandem cells, the amorphous Silicon does not have the right bandgap to couple photons efficiently with the nano Silicon, i.e., the amorphous Silicon top cell has too large a bandgap and cannot produce the current matching (15 mA/cm²) needed to match the high current (15 mA/cm²) produced by the bottom nano Silicon cell in an optimum tandem configuration. Additionally, the amorphous Silicon degrades under light due to defect creation (the Staebeler-Wronski effect). That is why the tandem cells based on amorphous Silicon nano Silicon degrade by approximately 10% over time, which is an unacceptable loss in performance.

To address these problems, superlattice structures for nanocrystalline solar cells have been developed by the inventor of the instant application and other researchers at the Iowa State University. Indeed, such superlattice structures for nanocrystalline Silicon solar cells are described in a paper by V. L. Dalal and A. Madhavan entitled “Alternative Designs for Nanocrystalline Silicon Solar Cells” published by the Journal of Non-Crystalline Solids, 354, 2403-2406 (2008), the teachings and disclosure of which are incorporated in their entireties by reference thereto. Such a superlattice structure utilizes alternating amorphous and nanocrystalline layers and may be fabricated as described in a paper by A. Madhavan, V. L. Dalal, and M. A. Noack, entitled “Superlattice Structures for Nanocrystalline Silicon Solar Cells”, 978-1-4244-2030-8/08 published by IEEE, the teachings and disclosure of which are hereby incorporated in their entireties by reference thereto.

The superlattice nanocrystalline Silicon solar cell utilizes a standard cell design of a p+/n/n+ cell on stainless steel with a top ITO contact. The alternating layers of amorphous Silicon and nanocrystalline Silicon in the middle n layer are fabricated by alternating the power levels, with high power (approximately 25 W) leading to nanocrystalline Silicon, and low power (approximately 3 W) leading to amorphous Silicon. The function of the amorphous layers is to terminate the grain growth beyond a certain thickness in the nanocrystalline layer and start all over again in the next cycle. The thickness of each layer within a stack can be individually varied by varying the growth time. Indeed, for a given nanocrystalline Silicon layer thickness, the open circuit voltage of the cell increases with increasing amorphous Silicon layer thickness because the thicker barrier reduces the flow of reverse saturation current. As such, increasing the thickness of the barrier amorphous Silicon layer allows for an increase in the open circuit voltage, thereby increasing the efficiency of the overall superlattice cell structure. Further, for a given amorphous Silicon layer growth time, the open circuit voltage increases with increasing nanocrystalline growth time, which is logical as the crystallinity would be expected to increase with increasing grain size.

While the material and manufacturing costs, as well as the manufacturing complexity, is greatly reduced, the superlattice solar cell efficiency achieved with this basic structure is only approximately 8%. As such, improvements in the superlattice structures for nanocrystalline Silicon solar cells is needed in order to compete with the 14-15% conversion efficiency of the crystalline Silicon base modules. Embodiments of the present invention provide such improvements.

These and other advantages of the invention, as well as additional inventive features, will be apparent from the description of embodiments of the invention provided herein.

### BRIEF SUMMARY OF THE INVENTION

In view of the above, embodiments of the present invention provide a new and improved nanocrystalline superlattice solar cell that overcomes one or more of the problems existing in the art. More specifically, embodiments of the present invention provide new and improved nanocrystalline superlattice solar cells utilizing Germanium or an alloy of silicon and germanium in the construction of the superlattice middle layer of the solar cell.

In one embodiment the nanocrystalline superlattice solar cell includes a substrate on which an n+ layer is deposited. On top of this n+ doped layer is deposited a superlattice having alternating amorphous and nanocrystalline layers. On top of the superlattice is deposited a P-doped nanocrystalline or amorphous layer to complete the basic solar cell structure. The solar cell is completed by depositing a transparent conductor on the top p+ layer.

In one embodiment the superlattice includes alternating layers of amorphous Silicon Germanium alloy (a-(Si,Ge):H) and nanocrystalline Silicon. The percentage content of Germanium in the amorphous layer may be held constant across the amorphous layer, or may be graded with an increasing Germanium content as the amorphous layer is deposited. The grading may be continuous or discontinuous, and may vary from a starting percentage of Germanium to an ending percentage of Germanium across the amorphous layer. The starting Germanium content may be 0% or greater, and the ending percentage may be 100% or less. The number of alternating layers may vary as desired, and typically will be 50 layers or less. In one embodiment the first amorphous layer of the superlattice is thinner than subsequent amorphous layers and does not contain any Germanium content whatsoever.

Other aspects, objectives and advantages of the invention will become more apparent from the following detailed description when taken in conjunction with the accompanying drawings.

### BRIEF DESCRIPTION OF THE DRAWINGS

The accompanying drawings incorporated in and forming a part of the specification illustrate several aspects of the present invention and, together with the description, serve to explain the principles of the invention. In the drawings:

FIG. 1 is a simplified structure diagram of an embodiment of a nanocrystalline superlattice solar cell constructed in accordance with the teachings of the present invention;

FIG. 2 is a simplified valence diagram illustrating the bandgap differences between the amorphous and nanocrystalline layers of an embodiment of a superlattice constructed in accordance with the teachings of the present invention;

FIG. 3 is an alternate embodiment of a nanocrystalline superlattice solar cell constructed in accordance with the teachings of the present invention;

FIG. 4 is a simplified valence diagram showing decreasing bandgap energy with increasing Germanium content across an amorphous layer of an embodiment of the superlattice constructed in accordance with the teachings of the present invention;

FIG. 5 is a simplified structure diagram illustrating construction of an alternate embodiment of an amorphous layer of a superlattice constructed in accordance with the teachings of the present invention utilizing discreet step increases of Germanium content among sub-layers thereof;

FIG. 6 is a simplified valence diagram illustrating the discreet reduction in bandgap across the amorphous layer of FIG. 5; and

FIG. 7 is a graphical illustration comparing the normalized QE of a device constructed in accordance with the teachings of the present invention with a prior nanocrystalline superlattice solar cell.

While the invention will be described in connection with certain preferred embodiments, there is no intent to limit it to those embodiments. On the contrary, the intent is to cover all alternatives, modifications and equivalents as included within the spirit and scope of the invention as defined by the appended claims.

### DETAILED DESCRIPTION OF THE INVENTION

As discussed in the two papers identified and incorporated above, a superlattice solar cell having alternative layers of amorphous Si and nanocrystalline Si can be fabricated and has advantages from a manufacturing viewpoint. Embodiments of the present invention include new superlattice solar cell devices which exhibit significantly better performance than the superlattice solar cells described in these papers while utilizing the beneficial manufacturing techniques and structure described therein.

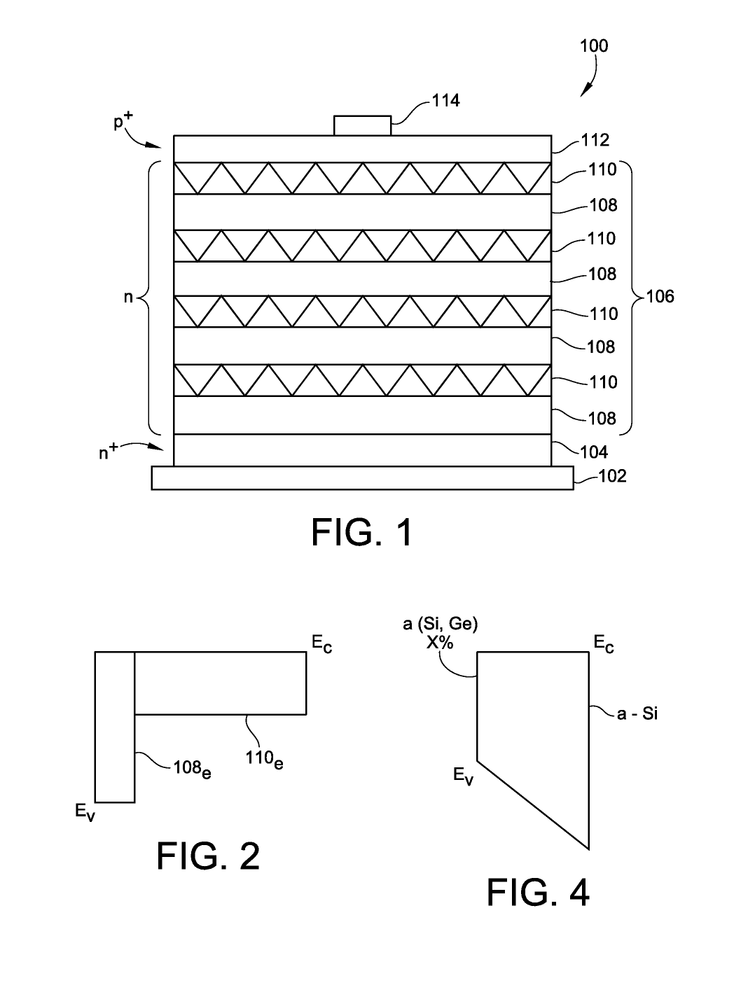

FIG. 1 is a schematic diagram of an embodiment of one such new superlattice solar cell 100. The superlattice solar cell 100 utilizes a suitable substrate 102, which can be any metal such as steel, Aluminum, silver etc., or an insulator such as plastic or glass coated with a metal, or any other suitable conducting layer such as doped ZnO or ITO. On top of that substrate 102 is coated a layer 104 of n+ amorphous Si, or a n+ doped alloy of a-(Si,Ge), or a-(Si,C), or nanocrystalline Si or nanocrystalline(nano) (Si,C) or nano alloy of (Si,Ge) or nano Ge. This layer is identified as an n+ layer in FIG. 1. An advantage of using other back n+ layers 104 such as a-(Si,C) is that more light is transmitted through them to the back reflector, and thus, more light is available for reflection back into the superlattice 106 (discussed below), thereby further increasing the current produced in the superlattice solar cell 100.

On top of this doped layer 104 is deposited a superlattice 106. The superlattice 106 includes alternating amorphous layers 108 of a-Si:H or a-(Si,Ge):H, which is an alloy of Si and Ge, or a-Ge:H, and nanocrystalline layers 110 of nanocrystalline Si:H, or nanocrystalline (Si,Ge):H, or nanocrystalline Ge:H, or nanocrystalline (Si,C):H. The amorphous layers 108 may have thickness ranging from about 1 nm to about 30 nm, and the nanocrystalline layers 110 may have thickness ranging from about 1 nm to 100 nm. This cycle of amorphous layer 108 and nanocrystalline layer 110 is repeated until the total desired thickness of this middle undoped or doped “base” layer (the superlattice 106) of the solar cell 100 is reached. This total desired thickness of this middle base layer (the superlattice 106) may vary between a few nm to several micrometer (e.g. 10 micrometer). The superlattice 106 may be doped n type deliberately, or be undoped while acquiring a doping due to a native dopant such as oxygen.

This “base” superlattice 106 layer is followed by a p-doped nanocrystalline or amorphous layer 112 composed of either Si, or an alloy of Si and Ge, or an alloy of Si and C. This layer 112 completes the basic cell structure, namely a p+(or p)-i(or n)-n+(or n) device. The middle i or n layer is the superlattice 106 layer. The superlattice solar cell 100 is completed by depositing a final transparent conductor 114 such as doped ZnO or ITO.

As discussed in the incorporated papers, the various layers can be deposited using well known techniques such as plasma-CVD deposition or hot wire deposition or sputtering. The contact layers such as ZnO and ITO can be deposited using other well known techniques such as sputtering, evaporation and CVD.

As discussed above only the basic steel/n+ a-Si/{superlattice including a-Si and nc-Si}/p+/ITO structure is disclosed in the incorporated papers, and such structure resulted in only an approximate 8% conversion efficiency. The inclusion of alternative materials such as (Si,Ge) in either the amorphous layers 108 or nanocrystalline layers 110 is completely new. The advantage of such a new development is that a-(Si,Ge) or a-Ge layer, instead of a-Si, absorbs infrared light of wavelength >600 nm much more efficiently than a-Si. Thus, embodiments of the present invention benefit from light absorption in both the amorphous layers 108 and the nanocrystalline layers 110, thereby adding significantly to current generated in the solar cell 100. Thus, embodiments of the present invention are much more efficient solar cells than the one described in the above incorporated papers.

The amount of light absorbed by the solar cell 100 may be tuned by tuning the alloy content Si:Ge. Higher Ge content in the alloy leads to a smaller bandgap and more light absorption as may be seen from the simplified valence diagram of FIG. 2. Yet another advantage of using a-(Si,Ge) instead of a-Si for the superlattice 106 is that the valence band mismatch between the amorphous layer 108 (bandgap for the amorphous layer 108 shown as 108ₑ in FIG. 2) and the nanocrystalline layer 110 (bandgap for the nanocrystalline layer 108 shown as 110ₑ in FIG. 2) phases is much less in (Si,Ge) alloys than between the two Silicons. Indeed, as the amount of Ge in the amorphous layer 108 is increased, the bandgap 108ₑ decreases, as does the mismatch between it and the bandgap 110ₑ for the nanocrystalline layer 110. This makes for more efficient collection of photo-generated holes in embodiments of the superlattice solar cell 100 compared to the standard device of the incorporated papers discussed above.

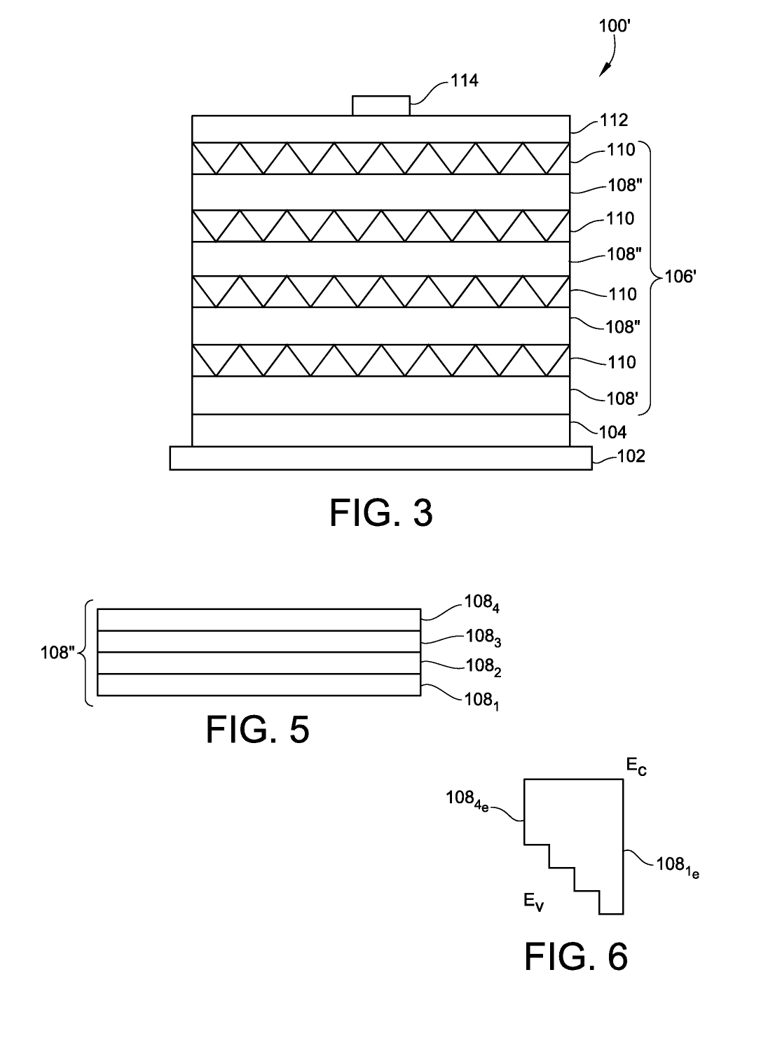

Indeed, while the embodiment of the supperlattice solar cell 100 of FIG. 1 utilizes a homogeneous amorphous layer 108 of a-(Si,Ge):H, in the embodiment of the superlattice solar cell 100′ shown in FIG. 3, the amount of Germanium in the amorphous layer 108″ is graded such that its content increases as the amorphous layer 108″ is deposited. This grading may range from 0% Germanium content at the initial (lower) boundary with the nanocrystalline layer 110 up to 100% at the upper boundary with the next nanocrystalline layer 110 to be grown. In one embodiment, the grading of the Germanium content in the amorphous layer ranges from 0% to approximately 15-20%.

This grading of the Germanium content results in a variation in the bandgap between the valence band energy (Eᵥ) and the conduction band energy (E_{c}) across the amorphous layer 108″ as shown by the simplified valence diagram of FIG. 4. As may be seen from an analysis of this FIG. 4, the bandgap at the initial interface with the previous nanocrystalline layer 110 is that of the undoped amorphous Silicon. This bandgap decreases with increasing Germanium content until the termination of the amorphous layer 108″ (illustrated as a-(Si,Ge) X % in FIG. 4). As discussed above, the amount of bandgap reduction is dependent upon the percentage content of the Germanium across the amorphous layer 108″. Indeed, while FIG. 4 illustrates an initial bandgap determined solely by undoped amorphous Silicon, embodiments of the present invention may begin the growth of this amorphous layer 108″ with some predetermined starting percentage content of Germanium such that this initial bandgap at the interface between the amorphous layer 108″ and the preceding nanocrystalline layer 110 may be less than that of undoped amorphous Silicon.

The grading of the Germanium content in the amorphous layer 108″ may be continuous, resulting in a continuous variation in the bandgap such as that illustrated in FIG. 4, or may occur in discreet steps of increasing Germanium content during the growth of the amorphous layer 108″. FIG. 5 illustrates one such example of an amorphous layer 108″ that utilizes discreet steps of increasing Germanium content during the fabrication of the amorphous layer 108″.

As illustrated in this FIG. 5, the amorphous layer 108″ includes a first sub-layer 108₁ having a first percentage content of Germanium. This percentage may be zero or higher. After this first sub-layer 108₁ has been deposited, the Germanium content is increased to a second level and held constant during the deposition of the second sub-layer 108₂. Once this second sub-layer 108₂ has been deposited, the percentage content of Germanium is again increased and then held constant during the deposition of the third sub-layer 108₃. This process is again repeated for the deposition of the fourth sub-layer 108₄ to complete the amorphous layer 108″.

When such a discreet step increase grading of the Germanium content is utilized, the decreasing bandgap across this amorphous layer 108″ appears as shown in the simplified valence diagram of FIG. 6. As this FIG. 6 illustrates, the bandgap 108₁ₑ for the first sub-layer 108₁ is reduced for each subsequent sub-layer until the bandgap 108₄ₑ in discreet steps resulting from the discreet step increases in the Germanium content. It should be noted, however, that while the illustration of FIG. 5 shows four sub-layers of increasing Germanium content to construct the amorphous layer 108″, more or fewer discreet steps may be employed.

In an exemplary embodiment of the nanocrystalline superlattice solar cell 100′, the superlattice 106′ was constructed in fifteen cycles, (i.e., thirty alternating layers). However, it should be noted that the invention is not limited to this number of layers and fewer or more layers, e.g., fifty layers, may be utilized. In this exemplary embodiment a first amorphous layer 108′ of undoped amorphous Silicon was grown for 30 seconds using the method described in the above-identified and incorporated papers. The nanocrystalline layer 110 was then deposited for 180 seconds. The amorphous layers 108″ were then grown for a total of 60 seconds. Specifically, each individual sub-layer 108₁₋₄ were deposited in 15 second increments utilizing a stepwise increase in the Germanium content from 3% in sub-layer 108₁ to 15% in sub-layer 108₄.

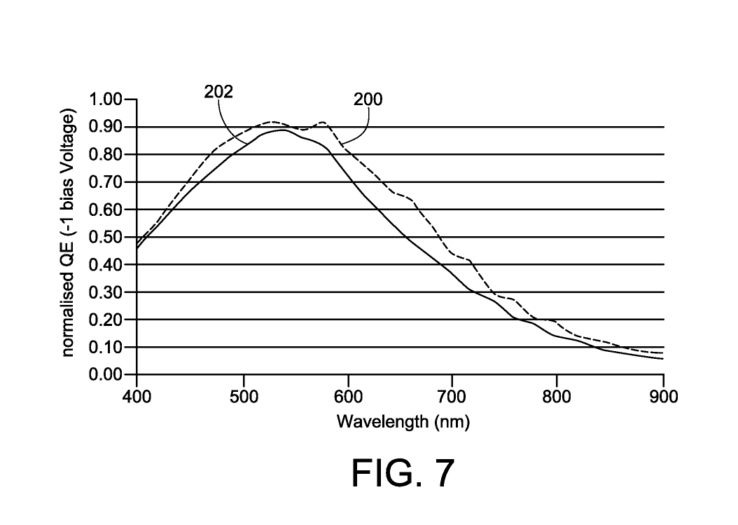

Testing of this exemplary embodiment reveals a significant improvement over the superlattice solar cells constructed in accordance with the teachings of the above-identified and incorporated papers as may be seen from a comparison of trace 200 of FIG. 7 for this exemplary embodiment and trace 202 for a similarly constructed embodiment having no Germanium in the amorphous Silicon layers.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventor for carrying out the invention. Variations of those preferred embodiments may become apparent to those of ordinary skill in the art upon reading the foregoing description. Indeed, one such variation in the structure of a superlattice solar cell includes grading of the bandgap of the nanocrystalline part of the superlattice, i.e the changing of the composition continuously or discretely from Si at the beginning of the nanocrystalline layer to Ge towards the end, or any mixture ranging from 0% Ge to 100% in-between. The inventor expects skilled artisans to employ such variations as appropriate, and the inventor intends for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A nanocrystalline superlattice solar cell, comprising:
a substrate;
an n+ layer deposited on the substrate;
a superlattice deposited on the n+ layer, the superlattice including alternating amorphous layers and nanocrystalline layers;
a p+ layer deposited on the superlattice; and
a transparent conductor deposited on the p+ layer; and
wherein at least one of the amorphous layers of the superlattice includes Germanium.

2. The nanocrystalline superlattice solar cell of claim 1, wherein the at least one amorphous layer including Germanium comprises a homogeneous a-(Si,Ge):H layer.

3. The nanocrystalline superlattice solar cell of claim 2, wherein the homogeneous a-(Si,Ge):H layer contains between 15-20% Germanium.

4. The nanocrystalline superlattice solar cell of claim 1, wherein the at least one amorphous layers including Germanium comprises a graded a-(Si,Ge):H layer.

5. The nanocrystalline superlattice solar cell of claim 4, wherein a content of Germanium in the graded a-(Si,Ge):H layer varies from a first percentage at a starting of the graded a-(Si,Ge):H layer and increases to a second percentage at an ending of the graded a-(Si,Ge):H layer.

6. The nanocrystalline superlattice solar cell of claim 5, wherein the first percentage is greater than or equal to zero.

7. The nanocrystalline superlattice solar cell of claim 5, wherein the first percentage is greater than zero.

8. The nanocrystalline superlattice solar cell of claim 5, wherein the first percentage is equal to zero.

9. The nanocrystalline superlattice solar cell of claim 5, wherein the second percentage is less than or equal to one hundred.

10. The nanocrystalline superlattice solar cell of claim 5, wherein the second percentage is less than one hundred.

11. The nanocrystalline superlattice solar cell of claim 10, wherein the second percentage is between approximately 15-20%.

12. The nanocrystalline superlattice solar cell of claim 11, wherein the first percentage is equal to zero.

13. The nanocrystalline superlattice solar cell of claim 5, wherein the second percentage is equal to one hundred.

14. The nanocrystalline superlattice solar cell of claim 4, wherein the graded a-(Si,Ge):H layer has a continuously increasing Germanium content.

15. The nanocrystalline superlattice solar cell of claim 4, wherein the graded a-(Si,Ge):H layer has a discontinuously increasing Germanium content.

16. The nanocrystalline superlattice solar cell of claim 4, wherein the graded a-(Si,Ge):H layer has a stepwise increasing Germanium content.

17. The nanocrystalline superlattice solar cell of claim 16, wherein the graded a-(Si,Ge):H layer comprises a plurality of sublayers, and wherein each of the plurality of sublayers has an increased Germanium content from a previous sublayer.

18. The nanocrystalline superlattice solar cell of claim 17, wherein a first sublayer has a zero Germanium content.

19. The nanocrystalline superlattice solar cell of claim 1, wherein all of the amorphous layers of the superlattice comprise a-(Si,Ge):H.

20. The nanocrystalline superlattice solar cell of claim 19, wherein all of the amorphous layers of the superlattice comprise homogeneous a-(Si,Ge):H layers.

21. The nanocrystalline superlattice solar cell of claim 19, wherein all of the amorphous layers of the superlattice comprise graded a-(Si,Ge):H layers.

22. The nanocrystalline superlattice solar cell of claim 21, wherein the graded a-(Si,Ge):H layers have continuously increasing Germanium content.

23. The nanocrystalline superlattice solar cell of claim 21, wherein the graded a-(Si,Ge):H layers have discontinuously increasing Germanium content.

24. The nanocrystalline superlattice solar cell of claim 1, wherein all but a first of the amorphous layers of the superlattice comprise a-(Si,Ge):H.

25. The nanocrystalline superlattice solar cell of claim 24, wherein all but a first of the amorphous layers of the superlattice comprise homogeneous a-(Si,Ge):H layers.

26. The nanocrystalline superlattice solar cell of claim 24, wherein all but a first of the amorphous layers of the superlattice comprise graded a-(Si,Ge):H layers.

27. The nanocrystalline superlattice solar cell of claim 26, wherein the graded a-(Si,Ge):H layers have continuously increasing Germanium content.

28. The nanocrystalline superlattice solar cell of claim 26, wherein the graded a-(Si,Ge):H layers have discontinuously increasing Germanium content.

29. The nanocrystalline superlattice solar cell of claim 1, wherein the superlattice includes up to fifty total layers of alternating amorphous layers and nanocrystalline layers.

30. The nanocrystalline superlattice solar cell of claim 29, wherein the superlattice includes thirty total layers of alternating amorphous layers and nanocrystalline layers.

31. The nanocrystalline superlattice solar cell of claim 30, wherein all but a first of the amorphous layers comprise a-(Si,Ge):H.

32. The nanocrystalline superlattice solar cell of claim 1, wherein the nanocrystalline layers comprise nanocrystalline Si:H.

33. The nanocrystalline superlattice solar cell of claim 1, wherein the nanocrystalline layers comprise nanocrystalline (Si,Ge):H.

34. The nanocrystalline superlattice solar cell of claim 33, wherein at least one of the nanocrystalline (Si,Ge):H layers comprises a graded nanocrystalline (Si,Ge):H layer.

35. The nanocrystalline superlattice solar cell of claim 33, wherein a content of Germanium in the graded nanocrystalline (Si,Ge):H layer varies from a first percentage at a starting of the graded nanocrystalline (Si,Ge):H layer and increases to a second percentage at an ending of the graded nanocrystalline (Si,Ge):H layer.

36. The nanocrystalline superlattice solar cell of claim 1, wherein the nanocrystalline layers comprise nanocrystalline Ge:H.

37. The nanocrystalline superlattice solar cell of claim 1, wherein the nanocrystalline layers comprise nanocrystalline (Si,C):H.

38. The nanocrystalline superlattice solar cell of claim 1, wherein the nanocrystalline layers have a thickness of between approximately 1 nm to 100 nm.

39. The nanocrystalline superlattice solar cell of claim 1, wherein the amorphous layers have a thickness of between approximately 1 nm to 30 nm.

40. The nanocrystalline superlattice solar cell of claim 1, wherein the superlattice has a thickness of between approximately 2 nm to 10 mm.

41. The nanocrystalline superlattice solar cell of claim 1, wherein at least one of the nanocrystalline layers of the superlattice includes Germanium, and wherein a content of the Germanium is graded from a first percentage at a starting of the nanocrystalline layer and increases to a second percentage at an ending of the nanocrystalline layer.

42. A superlattice for use in a solar cell as a middle i layer in a p+-i-n+ cell structure, the superlattice comprising:
a plurality of alternating amorphous layers and nanocrystalline layers; and
wherein at least one of the amorphous layers includes Germanium.

43. The superlattice of claim 42, wherein the at least one amorphous layer including Germanium comprises a homogeneous a-(Si,Ge):H layer.

44. The superlattice of claim 42, wherein the at least one amorphous layer including Germanium comprises a graded a-(Si,Ge):H layer.

45. The superlattice of claim 44, wherein a content of Germanium in the graded a-(Si,Ge):H layer varies from a first percentage at a starting of the graded a-(Si,Ge):H layer and increases to a second percentage at an ending of the graded a-(Si,Ge):H layer.

46. The superlattice of claim 42, wherein at least one of the nanocrystalline layers includes Germanium, and wherein the at least one nanocrystalline layer including Germanium comprises a graded nanocrystalline (Si,Ge):H layer.
